(19) United States
(12) Patent Application Publication
(10) Pub. No.: US 2015/0372137 A1
(43) Pub. Date: Dec. 24, 2015

(54) SEMICONDUCTOR DEVICE AND METHOD FOR MANUFACTURING SAME

(71) Applicants: Yasuyuki SAKOGAWA,, Chuo-ku, Tokyo (JP); (PS4 LUXCO S.AR.L.), Luxembourg (LU)

(72) Inventor: Yasuyuki Sakogawa, Tokyo (JP)

(21) Appl. No.: 14/764,970

(22) PCT Filed: Jan. 29, 2014
(86) PCT No.: PCT/JP2014/051903

§ 371 Date: Jul. 30, 2015

(30) Foreign Application Priority Data
Feb. 1, 2013 (JP) 2013-018241

(51) Int. Cl. H01L 29/78; H01L 27/108; H01L 29/51

(52) U.S. Cl. CPC H01L 29/7831; H01L 29/517; H01L 27/10805

(57) ABSTRACT

A semiconductor device which is provided with: a gate insulating film which contains a high dielectric constant insulating material and has a first width; a lower gate electrode which has a second width that is narrower than the first width; an upper gate electrode which has a third width; and a first spacer layer which covers the lateral part of the upper gate electrode, a part of the lower part of the upper gate electrode, a part of the lower gate electrode, a part of the upper surface of the gate insulating film, said part of the upper surface being out of contact with the lower gate electrode, and the lateral surface of the gate insulating film.

### TECHNICAL FIELD

The present invention relates to a semiconductor device and a method of manufacturing the same, and in particular relates to a semiconductor device comprising field-effect transistors in which a gate insulating film containing a high dielectric-constant insulating material is formed, and a method of manufacturing the same.

### BACKGROUND ART

An HKMG construction has been proposed in order to resolve various problems that arise in conjunction with developments involving reductions in the power supply voltage and increases in the speed of semiconductor devices. A transistor having a HKMG (High-K Metal Gate) construction (hereinafter referred to as ‘HKMG transistor’) is a transistor provided with a gate insulating film containing a high dielectric-constant insulating material having a dielectric constant higher than that of silicon dioxide, and a gate electrode comprising a metal film. In an HKMG transistor, the inclusion of the high dielectric-constant insulating material in the gate insulating film makes it possible to suppress gate leakage currents while reducing the EOT (equivalent oxide thickness) thickness. Further, employing a gate electrode comprising a metal film makes it possible to improve the operating characteristics of the transistor. Meanwhile, it is known that in HKMG transistors the threshold voltage (Vₜ) shifts in accordance with the state of diffusion of oxygen in the high dielectric-constant gate insulating film being employed.

Japanese Patent Kokai 2009-283906 discloses a phenomenon whereby the Vₜ of a field-effect transistor changes if oxygen is supplied from the side surface of a high dielectric-constant insulating film after patterning.

IEEE Transactions on Electron Devices, Vol. 53, No. 9, September 2006 discloses a construction in which the gate electrode of a field-effect transistor is made finer in the vicinity of the gate insulating film.

### PATENT LITERATURE

Patent literature article 1: Japanese Patent Kokai 2009-283906

### Non-patent literature

Non-patent literature article 1: IEEE Transactions on Electron Devices, Vol. 53, No. 9, September 2006

### SUMMARY OF THE INVENTION

### Problems to be Resolved by the Invention

The problems in the related art will now be described, taking by way of example a case in which, in a process of manufacturing a DRAM (Dynamic Random Access Memory) in which bit lines in a memory cell region and gate electrodes in a peripheral circuit region are formed at the same time, an HKMG transistor is formed in the peripheral circuit region.

In the process of manufacturing a DRAM such as that described hereinabove, a problem arises in that penetration of oxidant or the like from the end portion of the gate insulating film in the peripheral circuit region causes the Vₜ of the HKMG transistor provided in the peripheral circuit region to increase. Accordingly, it is possible to suppress the increase in the Vₜ resulting from oxidant penetration, by increasing the thickness of a liner film which covers the end portion of the gate electrode in the HKMG transistor. However, the margin for openings for capacitor contacts provided in the memory cell region has become smaller as miniaturization has progressed, and it is thus difficult to form the capacitor contacts if the thickness of the liner film is increased. As described hereinabove, in the related art it is difficult to set the thickness of the liner film in such a way as to be suitable both for suppressing increases in the Vₜ of the HKMG transistors in the peripheral circuit region and for forming the capacitor contacts in the memory cell region.

FIGS. 13 and 14 are drawings illustrating in detail the problems in the related art described hereinabove. FIG. 13A is a cross-sectional view, and FIGS. 13B and 13C are respectively partial enlarged views of the parts B and C enclosed by the dotted lines in the cross-sectional view in FIG. 13A. Similarly, FIG. 14A is a cross-sectional view, and FIGS. 14B and 14C are respectively partial enlarged views of the parts B and C enclosed by the dotted lines in the cross-sectional view in FIG. 14A. It should be noted that in FIG. 13 and FIG. 14, only the structures of portions of the memory cell region and the peripheral circuit region are illustrated.

In this semiconductor device, first, as illustrated in FIG. 13, bit lines 501 and the like are formed in a memory cell region 2, and a gate insulating film 510 containing a high dielectric-constant insulating material, and a gate electrode 502 comprising polysilicon films 511 and 512 and a metal film 513, and the like, are formed in a peripheral circuit region 3. Liner films 551 and 552, which are silicon nitride films, are then formed in such a way as to cover the bit lines 501, and the liner film 551, which is a silicon nitride film, a spacer film 560, which is a TEOS film, and the liner film 552, which is a silicon nitride film, are formed in such a way as to cover the gate insulating film 510 and the gate electrode 502. At this time, during etch-back after deposition of the liner film 551, oxidant penetrates from the end portions of the gate insulating film 510 in the peripheral circuit region 3, causing oxidation to occur in the vicinity of the end portions of the gate insulating film 510, and thereby creating oxides DE as illustrated in FIG. 13C. The oxides D1 give rise to a similar effect to that which occurs if the thickness of the gate insulating film 510 is increased, and this causes a deterioration in the advantageous characteristic of HKMG transistors, namely that the EOT can be made thinner. Problems arise as a result, for example an increase in the Vₜ of the HKMG transistor.

Meanwhile, increasing the thickness of the liner film 551 makes it possible to suppress increases in the Vₜ of the HKMG transistors in the peripheral circuit region 3. However, as illustrated in FIG. 13B, the liner film 551 is formed not only in the peripheral circuit region 3, but also at the same time in the memory cell region 2. In recent years, the margin for openings for capacitor contacts (which are not shown in the drawings) formed between the bit lines 501 in the memory cell region 2 has become smaller as miniaturization of DRAMs has progressed. Therefore, if the thickness of the liner film 551 is increased, the space sections between the bit lines 501 in the memory cell region 2 become completely filled by the liner film 551, making it difficult to form the capacitor contacts.

Accordingly, a method has been proposed whereby a liner film 551′ which is a composite film comprising a silicon nitride film and a silicon dioxide film is formed instead of the liner film 551, as illustrated in FIG. 14. In this way, when the space film 560 in the memory cell region 2 is removed, the silicon dioxide film which is a constituent of the liner film 551′ on the side surfaces of the bit lines 501 is also removed, and the margin for the openings for the capacitor contacts in the memory cell region 2 can be ensured. However, with this method there is an additional step of depositing the silicon dioxide film when the liner film 551′ is formed, and this increases the manufacturing cost.

It should be noted that the problems in the related art have been described hereinabove taking by way of example a DRAM in which HKMG transistors are provided in the peripheral circuit region. However, besides this case, in semiconductor devices which are provided with field-effect transistors having a gate insulating film containing a high dielectric-constant insulating material, and in which miniaturization has progressed, it is, in the same way, also difficult to form a liner film having a thickness that is suitable both for suppressing increases in the Vₜ of the field-effect transistor, and for forming other sites in which miniaturization has progressed, such as contacts.

### Means of Overcoming the Problems

One mode of embodiment relates to a semiconductor device provided with a field-effect transistor comprising:

a gate insulating film which contains a high dielectric-constant insulating material, is provided with an upper surface, a bottom surface and two mutually-opposing side surfaces, is in contact at the bottom surface with a substrate, and has a first width defined by the spacing between the two side surfaces;
a lower gate electrode which opposes the substrate with the interposition of a portion of the gate insulating film, and which has a second width which is less than the first width in a direction parallel to the first width;
an upper gate electrode which covers the lower gate electrode, is provided with an upper portion, a lower portion and two mutually-opposing side portions, and has a third width in a direction parallel to the first width; and
a first spacer layer which covers the side portions of the upper gate electrode, a portion of the lower portion of the upper gate electrode, a portion of the lower gate electrode, a portion of the upper surface of the gate insulating film that is not in contact with the lower gate electrode, and the side surfaces of the gate insulating film.

Another mode of embodiment relates to a method of manufacturing a semiconductor device, comprising:

a step of forming on a substrate a gate insulating film containing a high dielectric-constant insulating material;
a step of forming a lower gate electrode on the gate insulating film;
a step of forming an upper gate electrode on the lower gate electrode;
a step of patterning the upper gate electrode and the lower gate electrode;
a step of side-etching the lower gate electrode to reduce a second width defined by the spacing between two mutually-opposing side surfaces of the lower gate electrode;
a step of selectively removing the gate insulating film in such a way that a first width of the gate insulating film in a direction parallel to the second width is greater than the second width; and
a step of forming a first spacer layer in such a way that it covers a side portion and
a lower portion of the upper gate electrode, a side surface of the lower gate electrode, and an exposed part of the upper surface and the side surface of the gate insulating film.

### Advantages of the Invention

An increase in the Vₜ of a field-effect transistor can be suppressed without increasing the manufacturing cost. It is also possible to provide a semiconductor device which supports miniaturization.

### BRIEF EXPLANATION OF THE DRAWINGS

FIG. 1 is a drawing used to describe a semiconductor device in a second mode of embodiment.

FIG. 2 is a drawing used to describe a semiconductor device in a third mode of embodiment.

FIG. 3 is a drawing used to describe a method of manufacturing the semiconductor device in the third mode of embodiment.

FIG. 4 is a drawing used to describe the method of manufacturing the semiconductor device in the third mode of embodiment.

FIG. 5 is a drawing used to describe the method of manufacturing the semiconductor device in the third mode of embodiment.

FIG. 6 is a drawing used to describe the method of manufacturing the semiconductor device in the third mode of embodiment.

FIG. 7 is a drawing used to describe the method of manufacturing the semiconductor device in the third mode of embodiment.

FIG. 8 is a drawing used to describe the method of manufacturing the semiconductor device in the third mode of embodiment.

FIG. 9 is a drawing used to describe the method of manufacturing the semiconductor device in the third mode of embodiment.

FIG. 10 is a drawing used to describe the method of manufacturing the semiconductor device in the third mode of embodiment.

FIG. 11 is a drawing used to describe the method of manufacturing the semiconductor device in the third mode of embodiment.

FIG. 12 is a drawing used to describe the method of manufacturing the semiconductor device in the third mode of embodiment.

FIG. 13 is a drawing used to describe the problems in a semiconductor device in the related art.

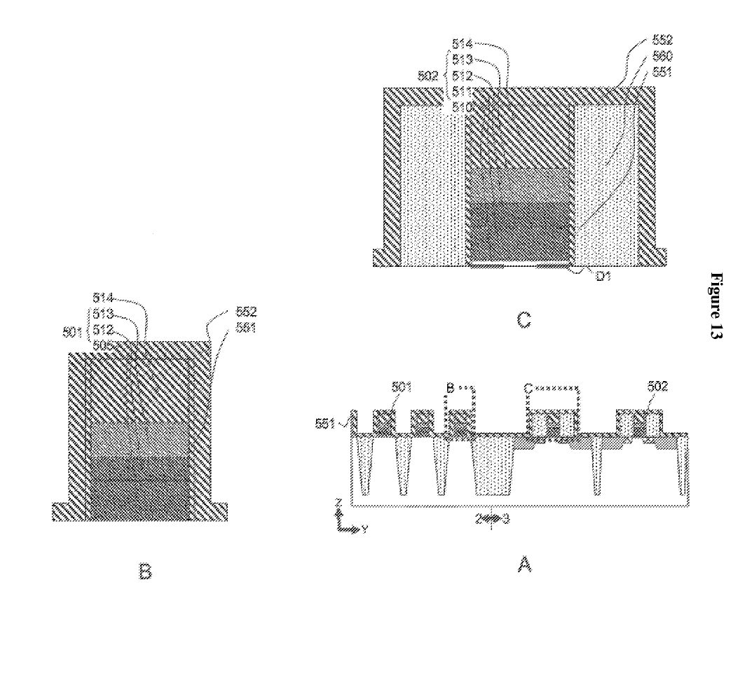

FIG. 14 is a drawing used to describe the problems in a semiconductor device in the related art.

### MODES OF EMBODYING THE INVENTION

Modes of embodying the present invention will now be described with reference to the drawings. These modes of embodiment are specific examples illustrated to provide a more in-depth understanding of the present invention, and the present invention is not in any way restricted to these specific examples. Further, the same reference codes are assigned to the same members, and explanations thereof are omitted or simplified. Reference codes are omitted as appropriate for identical members. It should be noted that the drawings used in the following description are schematic, and the ratios between length, width and thickness in each drawing are not necessarily the same as would actually be the case, and in some cases the ratios between length, width and thickness, and the hatching, for example, are not consistent between the drawings. In the following example, conditions such as materials and dimensions that are shown specifically are merely shown by way of example.

It should be noted that in the modes of embodiment described hereinbelow, ‘lower gate electrode’ described in the scope of the patent claims corresponds to the polysilicon films 511 and 512 which are constituents of the gate electrode 502.

‘Upper gate electrode’ described in the scope of the patent claims corresponds to the metal film 513 which is a constituent of the gate electrode 502.

‘First spacer layer’ and ‘second spacer layer’ described in the scope of the patent claims correspond respectively to the liner film 551 and the space film 560.

‘First impurity-diffused layer’ and ‘second impurity-diffused layer’ described in the scope of the patent claims correspond respectively to a peripheral LDD region 103 and a peripheral source and drain region 104.

‘First width’, ‘second width’ and ‘third width’ represent the widths (the spacing between two mutually-opposing side surfaces) of the gate insulating film 510, the lower gate electrodes (polysilicon films) 511 and 512, and the upper gate electrode (metal film) 513 respectively, in a direction which is perpendicular to the direction in which they respectively extend, and which is parallel to the substrate. For example, if the gate insulating film, the lower gate electrode and the upper gate electrode are rectangular as seen in a plan view, the ‘first width’, the ‘second width’ and the ‘third width’ respectively represent the widths in the directions of the short edges of the gate insulating film, the lower gate electrode and the upper gate electrode.

Further, ‘single-layer film thickness of the first spacer layer’ represents the thickness of the first spacer layer when a single layer of the first spacer layer has been formed on a plane (excluding steps).

### First Mode of Embodiment

A semiconductor device in a first mode of embodiment is provided with a planar field-effect transistor. A gate insulating film of the field-effect transistor contains a high dielectric-constant insulating material, is provided with an upper surface, a bottom surface and two mutually-opposing side surfaces, and has a first width defined by the spacing between the two side surfaces. A gate electrode of the field-effect transistor is provided with a lower gate electrode which opposes a substrate with the interposition of the gate insulating film, and an upper gate electrode which covers the lower gate electrode. The lower gate electrode has a second width which is less than the first width in a direction parallel to the first width. Further, a first spacer layer is provided in such a way as to cover a portion of the lower gate electrode, a portion of the upper surface of the gate insulating film that is not in contact with the lower gate electrode, and the side surfaces of the gate insulating film. The third width of the upper gate electrode in a direction parallel to the first width is preferably greater than the total thickness of the first width and twice the single-layer film thickness of the first spacer layer. In other words, the following formula (1) is preferably satisfied.

(Third width)>first width+(single-layer film thickness of first spacer layer)×2 (1)

Further, the single-layer film thickness of the first spacer layer is preferably at least equal to 1.4 times the thickness of the gate insulating film.

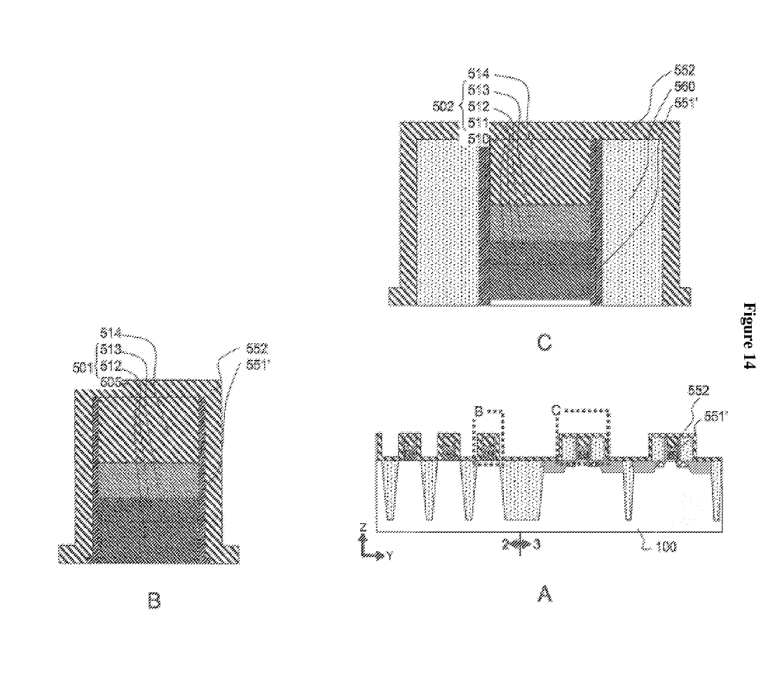

In this semiconductor device, the second width is less than the first width, and therefore a step is formed between the gate insulating film and the lower gate electrode. The thickness of the first spacer layer formed on the step comprising the lower gate electrode and the gate insulating film can therefore be made larger than the single-layer film thickness of the first spacer layer. The first spacer layer on the step (the upper surface and the side surfaces of the gate insulating film) is preferably thicker than the gate insulating film. Therefore in the process of manufacturing the field-effect transistor it is possible to prevent oxidant penetrating from the end portions of the gate insulating film, causing oxidation to occur in the vicinity of the end portions of the gate insulating film and thereby creating oxides. As a result, an increase in the Vₜ of the field-effect transistor can be effectively prevented. Further, a step of depositing a silicon dioxide film, such as that used when the liner film 551′ comprising the silicon nitride film and the silicon dioxide film in FIG. 14 is employed, is unnecessary, and therefore the manufacturing cost can be reduced. Further, the first spacer layer on the step is made uniformly thick in a self-aligned manner. It is therefore not necessary to increase the single-layer film thickness of the first spacer layer, and adverse effects on the formation of other sites in the semiconductor device can be prevented even if the semiconductor device is miniaturized. As a result, it is possible to provide a semiconductor device which supports miniaturization.

### Second Embodiment

The semiconductor device in a second mode of embodiment relates to a DRAM (Dynamic Random Access Memory), in which HKMG transistors are formed in a peripheral circuit region, and bit lines and memory cells are formed in a memory cell region. In the HKMG transistor, the gate insulating film contains a high dielectric-constant insulating material, and the gate electrode comprises a metal film, but the basic configuration thereof is the same as that of the field-effect transistor in the first mode of embodiment. Therefore in the semiconductor device in this mode of embodiment, the first spacer layer is formed on the step comprising the lower gate electrode and the gate insulating film. Further, the bit lines are formed from the same material as a portion of the gate electrode of the HKMG transistor, and the first spacer layer is also provided on the mutually-opposing side surfaces of the bit lines.

In this mode of embodiment:

(1) The thickness of the first spacer layer on the step comprising the lower gate electrode and the gate insulating film in the peripheral circuit region is greater than the thickness of the first spacer layer on the side surfaces of the bit lines.
(2) The second width of the lower gate electrode in the peripheral circuit region is less than the third width of the upper gate electrode in a direction parallel to the first width.

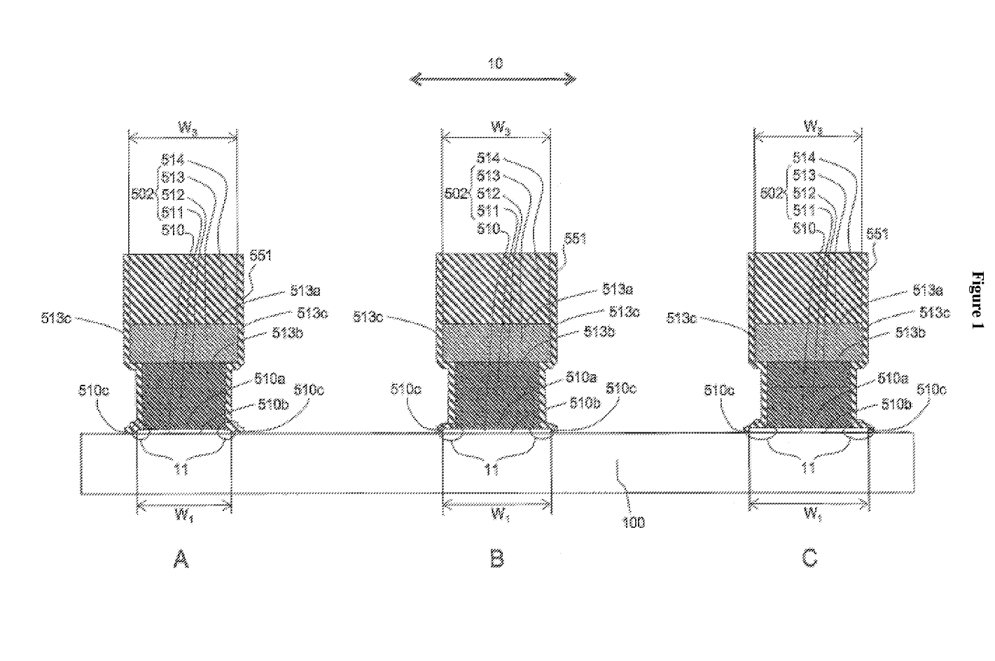

The characteristics of the semiconductor device in this mode of embodiment will now be described in detail with reference to FIG. 1. FIGS. 1A to C each represent cross-sections through the gate electrodes 502 of the HKMG transistors disposed in the peripheral circuit region, as seen in the direction in which the two side surfaces of the gate electrode face one another (described as ‘direction 10’ hereinafter). FIG. 1A illustrates a case in which the width (the first width) W₁ of the gate insulating film 510 in the direction 10 is less than the width (the third width) W₃ of the upper gate electrode (metal film 513) in the direction 10. FIG. 1B illustrates a case in which the third width W₃ and the first width W₁ are the same, and FIG. 1C illustrates a case in which the first width W₁ is greater than the third width W₃.

It should be noted that in FIGS. 1A to 1C, the gate insulating film 510, the gate electrode 502 and the first spacer layer 551, for example, of the HKMG transistors in the peripheral circuit region are illustrated, and other structures such as the memory cell region are omitted. Further, the gate electrode 502 is formed from the polysilicon films 511 and 512 and the metal film 513, and the polysilicon films 511 and 512 correspond to the lower gate electrode, and the metal film 513 corresponds to the upper gate electrode. The liner film 551 corresponds to the first spacer layer.

In each of the structures in FIGS. 1A to 1C, the gate insulating film 510 has an upper surface 510a, a bottom surface 510b, and two mutually-opposing side surfaces 510c, and is in contact with a semiconductor substrate 100 at the bottom surface 510b. The polysilicon films 511 and 512 oppose the semiconductor substrate 100 with the interposition of the gate insulating film 510. The metal film 513 covers the polysilicon films 511 and 512, and has an upper portion 513a, a lower portion 513b, and two mutually-opposing side portions 513c.

In FIGS. 1A and 1B, the liner film 551 is provided in such a way as to cover the side portions 513c of the metal film 513, a portion of the bottom portion 513b of the metal film 513, portions of the polysilicon films 511 and 512, a portion of the upper surface 510a of the gate insulating film 510 that is not in contact with the polysilicon film 511, and the side surfaces 510c of the gate insulating film 510.

A method of manufacturing the semiconductor device in this mode of embodiment will now be described with reference to FIG. 1B.

First, as illustrated in FIG. 1B, desired structures are formed in the memory cell region and the peripheral circuit region, after which the gate insulating film 510 is formed in the peripheral circuit region. The polysilicon films 511 and 512, the metal film 513 and a mask insulating film 514 are then formed successively in the memory cell region and the peripheral circuit region. The mask insulating film 514 is patterned to form a hardmask, after which the polysilicon films 511 and 512 and the metal film 513 are successively processed into the shapes of the bit lines and the gate electrode 502 by etching, using the hardmask. Further, the gate insulating film 510 is also processed by means of this etching. During this etching, etching is performed using conditions (highly-isotropic etching conditions) whereby the polysilicon films 511 and 512 are etched not only in the vertical direction but also in the horizontal direction. At this time, the hardmask pattern is set in such a way that the spacing between the gate electrodes 502 in the peripheral circuit region is wider than the spacing between the bit lines in the memory cell region. Because of this difference between the densities of the patterns for the bit lines and for the gate electrodes 502, the polysilicon film 512 forming the bit lines, and bit line plugs (none of which are shown in the drawings) are not etched in the horizontal direction. In contrast, the polysilicon films 511 and 512 forming the gate electrodes 502 in the peripheral circuit region are etched in the horizontal direction, and they become narrower. The second width of the polysilicon films 511 and 512 thus becomes less than the third width of the metal film 513. Further, a step 11 comprising the gate insulating film 510 and the polysilicon films 511 and 512 is formed.

The liner film (first spacer layer) 551 is then formed on the memory cell region and the peripheral circuit region, after which the liner film 551 on the peripheral circuit region is etched back. Here, in the memory cell region, the width of the metal film 513 and the width of the polysilicon film 512 are substantially the same. Therefore the thickness of the liner film formed on the side surfaces of the bit lines is also substantially the same thickness as the single-layer film of the liner film 551. Meanwhile, in the peripheral circuit region, because the step 11 comprising the gate insulating film 510 and the polysilicon films 511 and 512 has been formed, the liner film 511 remains in an L-shape on the step 11 after etch-back. In other words, the liner film 551 is provided in such a way as to cover the side portions 513c of the metal film 513, a portion of the bottom portion 513b of the metal film 513, portions of the polysilicon films 511 and 512, a portion of the upper surface 510a of the gate insulating film 510 that is not in contact with the polysilicon film 511, and the side surfaces 510c of the gate insulating film 510.

As a result, the thickness of the liner film 511 on the step 11 can be made larger than the thickness (single-layer film thickness) of the liner film formed on the side surfaces of the bit lines. It is therefore possible to prevent oxidant penetrating from the end portions of the gate insulating film 510, causing oxidation to occur in the vicinity of the end portions of the gate insulating film 510 and thereby creating oxides. As a result, an increase in the Vₜ of the HKMG transistor can be prevented. Further, a step of depositing a silicon dioxide film, such as that used when the liner film 551′ comprising the silicon nitride film and the silicon dioxide film in FIG. 14 is employed, is unnecessary, and therefore the manufacturing cost can be reduced. Further, the liner film 551 on the step 11 is made uniformly thick in a self-aligned manner. It is therefore not necessary to increase the single-layer film thickness of the liner film 551, and adverse effects on the formation of other sites in the semiconductor device can be prevented even if the semiconductor device is miniaturized. As a result, it is possible to provide a semiconductor device which supports miniaturization.

Here, if the first width of the gate insulating film 510 is less than the third width of the metal film 513, as illustrated in FIG. 1A, a large L-shaped portion of the liner film 551 forms on the step 11, and the thickness of the liner film 551 on the step 11 can be increased. As a result, an increase in the Vₜ of the HKMG transistor can be suppressed more effectively than in the case in FIG. 1B.

Meanwhile, if the first width of the gate insulating film 510 is greater than the third width of the metal film 513, as illustrated in FIG. 1C, the liner film 551 on the step 11 becomes thinner, or may be eliminated. In this case it is difficult to prevent oxidant penetration.

It is therefore preferable to adjust the etching conditions in such a way that the first width of the gate insulating film 510 is the same as the third width of the metal film 513 or is less than the third width.

### Third Embodiment

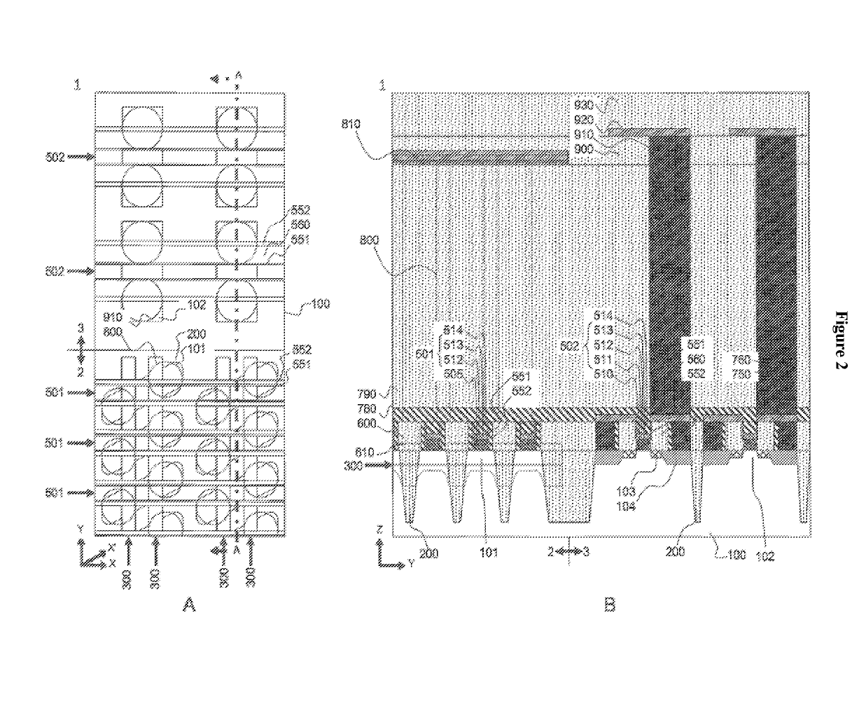

A semiconductor device in this mode of embodiment will now be described with reference to FIG. 2. FIG. 2A is a plan view illustrating the arrangement of the main parts of a DRAM 1, which is the semiconductor device in this mode of embodiment, and FIG. 2B is a cross-sectional view in the direction A-A in FIG. 2A. In FIG. 2A, constituent elements such as bit lines 501 in a memory cell region 2 and gate electrodes 502 in a peripheral circuit region 3 are drawn in a transparent manner in such a way that the structures therebelow can be seen. Further, FIG. 2A illustrates only the main structures.

As illustrated in FIGS. 2A and 2B, the memory cell region 2 and the peripheral circuit region 3 adjacent to the memory cell region 2 are disposed on a semiconductor substrate 100.

First, as illustrated in FIGS. 2A and 2B, memory cell active regions 101 in the shape of parallelograms, in which the semiconductor substrate 100 is divided by means of element isolation regions 200 in an X′-direction inclined from the X-direction, and in the Y-direction, are formed in the memory cell region 2. To elaborate, the memory cell active regions 101 are disposed in a repeating manner in the X′-direction and the Y-direction, sandwiching the element isolation regions 200. Two gate insulating films (which are not shown in the drawing) and two embedded word lines 300 are disposed extending in the Y-direction straddling a plurality of the memory cell active regions 101 aligned in the Y-direction and the element isolation regions 200 between the memory cell active regions 101, in such a way as to divide each memory cell active region 101 into three equal parts. There is no particular restriction to the material used for the gate insulating film, but a silicon dioxide film or the like can be used. There is no particular restriction to the material used for the embedded word lines 300, but a metal film or a laminated film comprising a barrier metal film and a metal film, or the like, can be used. Further, the upper surface of the embedded word lines 300 is located lower than the main surface of the semiconductor substrate 100, and a cover insulating film, which is not shown in the drawings, is disposed on the upper surface of the embedded word lines 300.

A bit contact interlayer film 610 is provided on the semiconductor substrate 100 in the memory cell region 2. The bit lines 501 are disposed, with the interposition of a first interlayer insulating film 600, extending in the X-direction in such a way as to connect, in the X-direction, a plurality of the parts (central parts) of the memory cell active regions 101 between the two embedded word lines 300, said memory cell active regions 101 being divided into three equal parts by the two embedded word lines 300. In other words, the bit lines 501 are disposed in a repeating manner in the memory cell region 2 with a specific spacing. The bit lines 501 are formed from a polysilicon film 512 and a metal film 513, and are connected to the central parts of the memory cell active regions 101 by means of bit line plugs 505 comprising polysilicon films. A mask insulating film 514, which is a silicon nitride film, is provided on the upper surface of the bit lines 501. A liner film 551, which is a silicon nitride film, and a liner film 552, which is similarly a silicon nitride film, are provided on the side surfaces of the bit lines 501. Further, both side parts of the memory cell active regions 101, divided into three equal parts by the two embedded word lines 300, are connected to capacitors 800 by way of capacitor contacts, which are not shown in the drawings.

Next, as illustrated in FIGS. 2A and 2B, rectangular peripheral circuit active regions 102, in which the semiconductor substrate 100 is divided by means of the element isolation regions 200 in the X-direction and in the Y-direction, are disposed in the peripheral circuit active region 3. To elaborate, the peripheral circuit active regions 102 are disposed in a repeating manner in the X-direction and the Y-direction, sandwiching the element isolation regions 200. It should be noted that the shape and the way in which the peripheral circuit active regions 102 are arranged may differ from those illustrated in FIG. 2. The gate electrodes 502 are disposed, with the interposition of the gate insulating film 510, extending in the X-direction, straddling a plurality of the peripheral circuit active regions 102 aligned in the Y-direction and the element isolation regions 200 between the peripheral circuit active regions 102, in such a way as to divide each peripheral circuit active region 102 into two equal parts. The gate electrodes 502 have the same structure as in FIG. 1B in the second mode of embodiment described hereinabove, and are formed from a lower gate electrode, which is the polysilicon films 511 and 512, and an upper gate electrode, which is the metal film 513. Further, the second width of the lower gate electrode in the direction (Y-direction) of the two side surfaces of the upper and lower gate electrodes is less than the first width, in the Y-direction, of the gate insulating film 510, and the third width, in the Y-direction, of the upper gate electrode. A step comprising the gate insulating film 510 and the lower gate electrode is thus formed. Further, the first width of the gate insulating film 510 is the same as the third width of the upper gate electrode.

A liner film (first spacer layer) 551, which is a silicon nitride film, a space film (second spacer layer) 560, which is a TEOS (Tetra Ethyl Ortho Silicate) film, and a liner film 552, which is a silicon nitride film, are disposed on the mutually-opposing side surfaces of the gate electrodes 502. The space film 560 is disposed in such a way as to cover the liner film 551 and a peripheral LDD region 103 in the vicinity of the liner film 551. The mask insulating film 514, which is a silicon nitride film, is provided on the metal film 513 of the gate electrodes 502. The width, in the Y-direction, of the mask insulating film 514 is the same as the width, in the Y-direction, of the metal film 513.

The peripheral LDD (Lightly Doped Drain) regions (first impurity-diffused layers) 103 are disposed in the peripheral circuit active regions 102 by implanting an impurity into the peripheral circuit active region 102 using the mask insulating film 514 and the liner film 551 as a mask. The peripheral LDD regions 103 are disposed on both sides of the gate insulating film 510 in the semiconductor substrate 100, along the liner films 551 as seen in a plan view. Further, peripheral source and drain (Source Drain) regions (second impurity-diffused layers) 104 are disposed in the peripheral circuit active regions 102 by implanting an impurity into the peripheral circuit active regions 102 using the mask insulating film 514, the liner film 551 and the space film 560 as a mask. The peripheral source and drain regions 104 are disposed on both sides of the gate insulating film 510 in the semiconductor substrate 100, along the space films 560 as seen in a plan view. Field-effect transistors are formed in the peripheral circuit region 3 from the gate insulating films 510, the gate electrodes 502, the mask insulating films 514, the peripheral LDD regions 103, the peripheral source and drain regions 104, the liner films 551 and 552, and the space films 560.

As illustrated in FIGS. 2A and 2B, the first interlayer insulating film 600 is disposed over the entire surface of the semiconductor substrate 100 in such a way as to embed the bit lines 501, the liner films 551 and the liner films 552 in the memory cell region 2, and the gate electrodes 502, the liner films 551, the space films 560 and the liner films 552 in the peripheral circuit region 3. As discussed hereinabove, in the memory cell region, capacitor contacts, which are not shown in the drawings, are disposed penetrating through the first interlayer insulating film 600 and the bit contact interlayer film 610, and connecting to the two parts of the memory cell active regions 101 to the outside of the two embedded word lines 300, from among the three equal parts into which the memory cell active regions 101 are divided by the two embedded word lines 300 in FIG. 2A. In the peripheral circuit region 3, peripheral contacts 750 are disposed penetrating through the first interlayer insulating film 600 in such a way as to connect to the peripheral source and drain regions 104. The peripheral contacts 750 are connected to peripheral wiring lines 760 provided on the first interlayer insulating film 600. Further, a stopper film 780, which is a silicon nitride film, and a thick (for example 1 μm) second interlayer insulating film 790 are disposed in such a way as to cover the upper surfaces of the first interlayer insulating film 600 and the peripheral wiring lines 760.

In the memory cell region 2, capacitors 800, comprising a lower electrode connected to the upper surface of the capacitor contact, a capacitative insulating film and an upper electrode, are disposed penetrating through the second interlayer insulating film 790 and the stopper film 780. It should be noted that in this mode of embodiment the capacitors 800 are cylinder-type capacitors in which the capacitative insulating film and the upper electrode are formed successively on the inner wall side surfaces and the inner wall bottom surface of the lower electrode. However, there is no particular restriction to the structure of the capacitors 800 provided that they are capable of accumulating electric charge. For example, the capacitors 800 may also be crown-type capacitors in which the capacitative insulating film and the upper electrode are formed successively on the inner wall side surfaces, the outer wall side surfaces and the inner wall bottom surface of the lower electrode. The upper electrodes of the capacitors 800 are connected to a plate electrode 810.

A third interlayer insulating film 900 is disposed on the second interlayer insulating film 790. In the peripheral circuit region 3, wiring line contacts 910 are provided penetrating through the stopper film 780, the second interlayer insulating film 790 and the third interlayer insulating film 900 in such a way as to connect to the peripheral wiring lines 760. Wiring lines 920 are provided on the third interlayer insulating film 900 in such a way as to connect to the wiring line contacts 910. A protective insulating film 930 is disposed on the third interlayer insulating film 900 in such a way as to cover the wiring lines 920.

In the same way as in the semiconductor device in FIG. 1B in the second mode of embodiment, in the semiconductor device in this mode of embodiment a step is formed from the gate insulating film 510 in the peripheral circuit region 3 and the polysilicon films 511 and 512. The liner film (first spacer layer) 551 is provided on this step, and therefore the thickness of the liner film 551 can be made larger, in a self-aligned manner, than the liner film 551 formed on the side surfaces of the bit lines 501. Therefore in the process of manufacturing the semiconductor device in this mode of embodiment it is possible to prevent oxidant penetrating from the end portions of the gate insulating film 510, thereby creating oxides in the gate insulating film 510. As a result, an increase in the Vₜ of the field-effect transistors disposed in the peripheral circuit region 3 can be effectively prevented. Further, a step of depositing a silicon dioxide film, such as that used when the liner film 551′ comprising the silicon nitride film and the silicon dioxide film in FIG. 14 is employed, is unnecessary, and therefore the manufacturing cost can be reduced. Further, because the liner film 551 becomes uniformly thick, in a self-aligned manner, on the step, it is not necessary to increase the single-layer film thickness of the liner film 551, and adverse effects on the formation of other sites in the semiconductor device can be prevented even if the semiconductor device is miniaturized. As a result, it is possible to provide a semiconductor device which supports miniaturization.

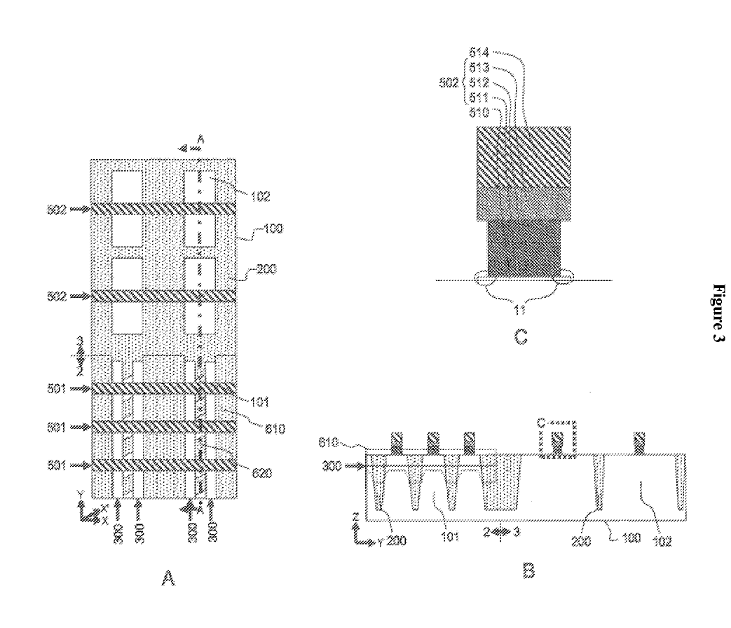

A method of manufacturing the semiconductor device in this mode of embodiment will now be described with reference to FIGS. 2 to 12. It should be noted that in FIGS. 3 to 12, Figure A is a plan view, Figure B is a cross-sectional view in the direction A-A in Figure A, and Figure C is a partial enlarged view of the part C enclosed by the dotted lines in Figure B, and in some cases Figure A is a perspective view illustrating only some of the structures.

First, as illustrated in FIG. 3, the element isolation regions 200 are formed in the semiconductor substrate 100 using a known technique, to divide the surface of the semiconductor substrate 100 into a plurality of memory cell active regions 101 and similarly a plurality of peripheral circuit active regions 102. An impurity having the opposite conduction type is implanted into each memory cell active region 101 by ion implantation to form impurity-diffused layers (which are not shown in the drawings) in the surfaces of the memory cell active regions 101. Trenches for embedded word lines are formed in the memory cell region 2 in such a way as to divide each memory cell active region 101 into three equal parts. In this way, the impurity-diffused layers in the surfaces of the memory cell active regions 101 are also divided into three equal parts. Gate insulating films (which are not shown in the drawings) are formed on the inner wall surfaces of the trenches by thermal oxidation of the inner wall surfaces of the trenches. A conductive film and an insulating film are then formed in such a way as to fill the trenches. In this way the embedded word lines 300, which are conductive films, and cover insulating films (which are not shown in the drawings), on the embedded word lines 300, are formed. This completes the formation of cell transistors in the memory cell region 2, the cell transistors being provided with the gate insulating films, the embedded word lines 300 and pairs of impurity-diffused layers formed in the surfaces of the memory cell active regions 101. It should be noted that two cell transistors are formed in each memory cell active region 101, and the central impurity-diffused layer, from among the three impurity-diffused layers which are divided into three equal parts by the two trenches, is shared between the two cell transistors. The bit contact interlayer film 610 is then formed in a prescribed region in the memory cell region 2.

The gate insulating film 510 including a high dielectric-constant insulating material is then formed on the surfaces of the peripheral circuit active regions 102 in the peripheral circuit region 3. The polysilicon film 511 is then formed on the peripheral circuit active regions 102 in the peripheral circuit region 3. Openings 620 are formed in the bit contact interlayer film 610 in such a way as to expose the central parts of the memory cell active regions 101 which have been divided into three equal parts by the two embedded word lines 300. The polysilicon film 512, the metal film 513 and the silicon nitride film 514 are formed successively on the semiconductor substrate 100 in the memory cell region 2 and the peripheral circuit region 3. The silicon nitride film 514 is patterned to form a mask insulating film pattern. At this time, the mask insulating film 514 pattern is set in such a way that the spacing (the spacing in the Y-direction) between the gate electrodes 502 in the peripheral circuit region 3 is wider than the spacing (the spacing in the Y-direction) between the bit lines 501 in the memory cell region 2. The metal film 513, the polysilicon films 512 and 511 and the gate insulating film 510 are then successively etched, using the mask insulating film 514 pattern as a mask. For this etching, the conditions (highly-isotropic etching conditions) are set in such a way that when the polysilicon films 511 and 512 are etched, etching progresses not only in the vertical direction of the polysilicon films 511 and 512, but also in the horizontal direction. At this time, the spacing between the patterns for the bit lines 501 is narrower than the spacing between the patterns for the gate electrodes 502. Thus, as a result of the difference between the densities of the patterns for the bit lines 501 and for the gate electrodes 502, the polysilicon film 512 forming the bit lines 501, and bit line plugs (which are not shown in the drawings) are not etched in the horizontal direction. In contrast, the polysilicon films 511 and 512 forming the gate electrodes 502 in the peripheral circuit region 3 are etched in the horizontal direction, and they become narrower. In this way, the second width of the polysilicon films (the lower gate electrode) 511 and 512 in the Y-direction is made smaller than the first width, in the Y-direction, of the gate insulating film 510, and the third width, in the Y-direction, of the metal film (the upper gate electrode) 513. The step 11 comprising the gate insulating film 510 and the lower gate electrode 511 and 512 is thus formed. Further, the bit lines 501 comprising the polysilicon film 512 and the metal film 513 are formed in the memory cell region 2, and the gate electrodes 502 comprising the polysilicon films 511 and 512 and the metal film 513 are formed in the peripheral circuit region 3.

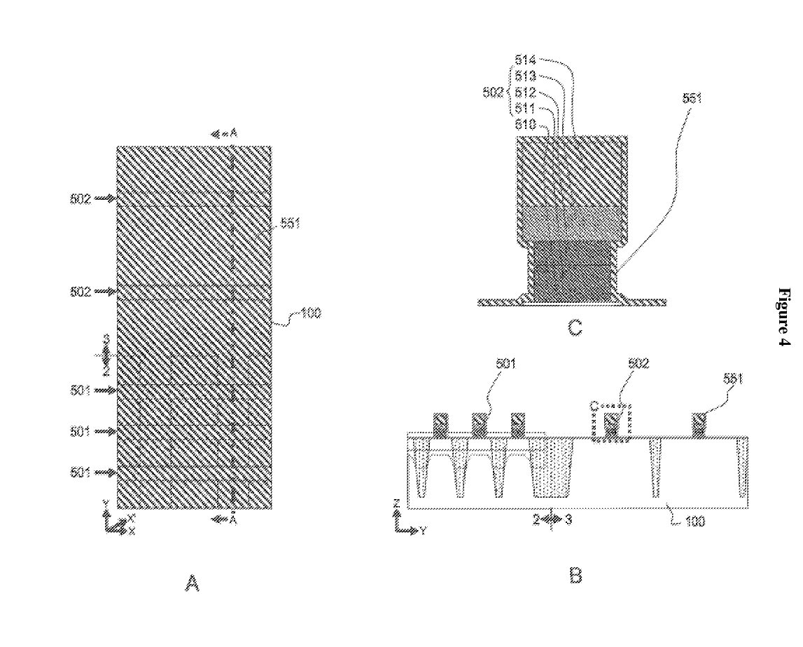

As illustrated in FIG. 4, the liner film 551, which is a silicon nitride film, is deposited by CVD over the entire surface of the semiconductor substrate 100 in the memory cell region 2 and the peripheral circuit region 3, in such a way as to cover the bit lines 501 and the gate electrodes 502.

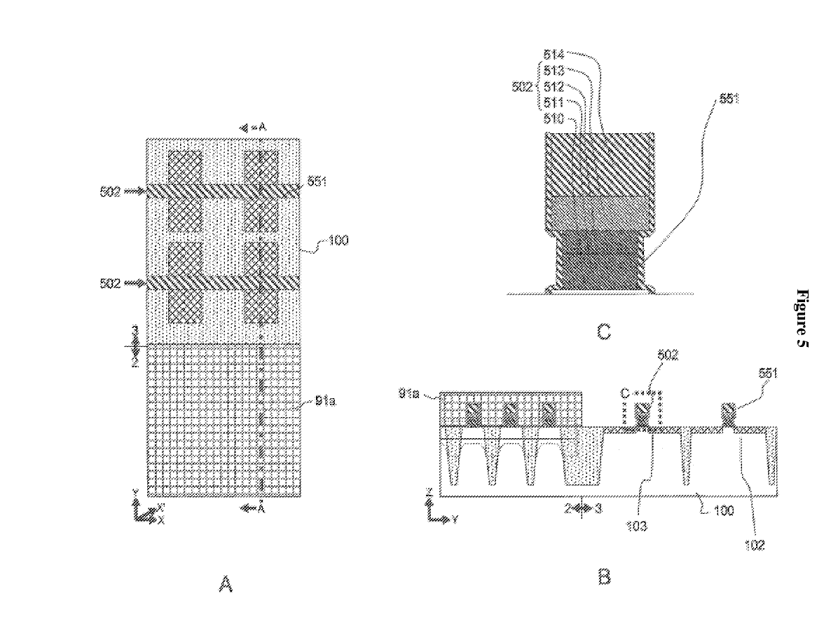

As illustrated in FIG. 5, a known lithographic technique is used to form a photoresist film 91a on the semiconductor substrate 100, in such a way as to cover the memory cell region 2. The liner film 551 is etched back, using the photoresist film 91a as a mask, leaving the liner film 551 in such a way that it is in contact with the side surfaces of the gate electrodes 502. At this time, as discussed hereinabove, because the step 11 comprising the gate insulating film 510 and the lower gate electrode 511 and 512 has been formed on the semiconductor substrate 100 in the peripheral circuit region 3, the liner film 551 remains in an L-shape on the step 11. Therefore the thickness of the liner film 551 on the step 11 can be made larger than that of the liner film 551 on the side surfaces of the bit lines 501 in the memory cell region 2. To elaborate, the thickness of the liner film 551 on the end portions (the exposed upper surface and side surfaces; the upper surface that is not in contact with the polysilicon film 511, and the side surfaces) of the gate insulating film 510 can be made larger in a self-aligned manner. By this means, penetration of oxidant into the gate insulating film 510, and oxidation in the vicinity of the end portions of the gate insulating film 510, are eliminated, and an increase in the Vₜ of the field-effect transistors in the peripheral circuit region 3 can therefore be suppressed. An impurity having the opposite characteristic to the peripheral circuit active regions 102 is then implanted by ion implantation into the peripheral circuit active regions 102, using the photoresist film 91a, and the mask insulating film 514 and the liner film 551 on the peripheral circuit region 3 as a mask, to form the peripheral LDD regions 103.

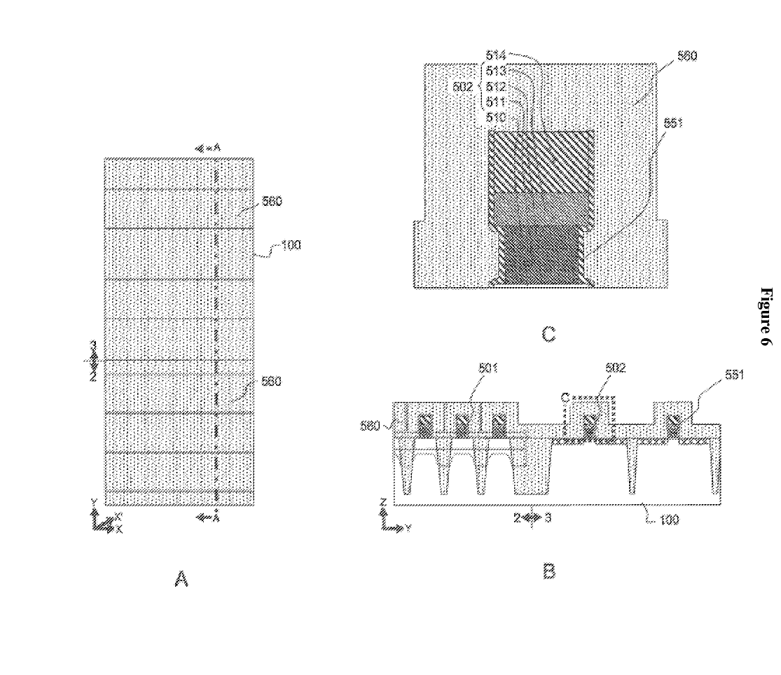

As illustrated in FIG. 6, the photoresist film 91a is then removed, after which the space film 560, for example a TEOS-BPSG film, is deposited by CVD over the entire surface of the semiconductor substrate 100, including the upper surfaces, and the side surfaces covered by the liner films 551, of the bit lines 501 and the gate electrodes 502. Here, because the gaps between the bit lines 501 in the memory cell region 2 are narrow, they are substantially filled by the space film 560.

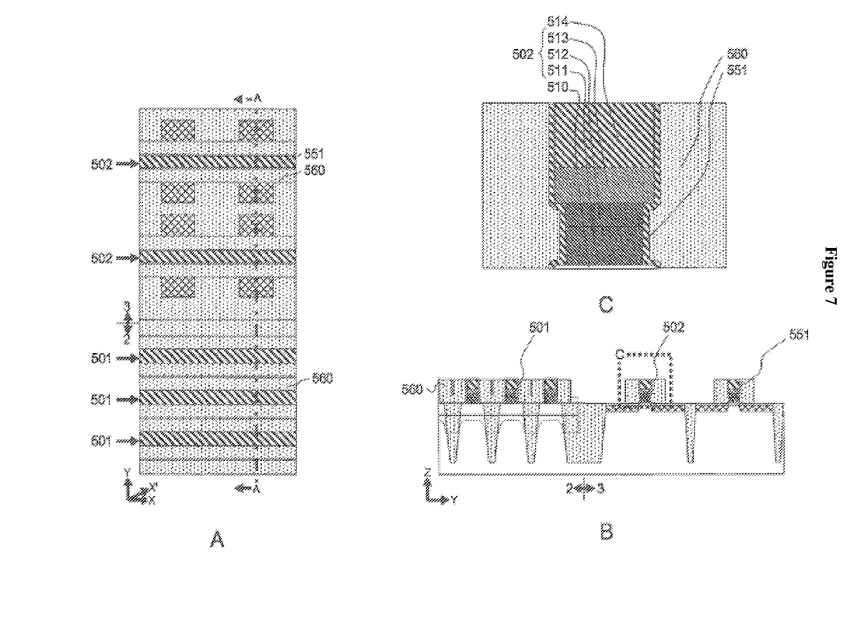

The space film 560 is then removed by etch-back, as illustrated in FIG. 7. At this time, the conditions are set in such a way that the parts of the space film 560 in contact with the bit lines 501 in the memory cell region 2, and the parts of the space film 560 in contact with the side surfaces of the gate electrodes 502 that are covered by the liner films 551, remain. In other words, in the memory cell region 2 the spacing between the bit lines 501 is narrow, and therefore adjacent space films 560 are in contact with one another, and therefore the gaps between the bit lines 501 are filled by the liner film 551 and the space film 560.

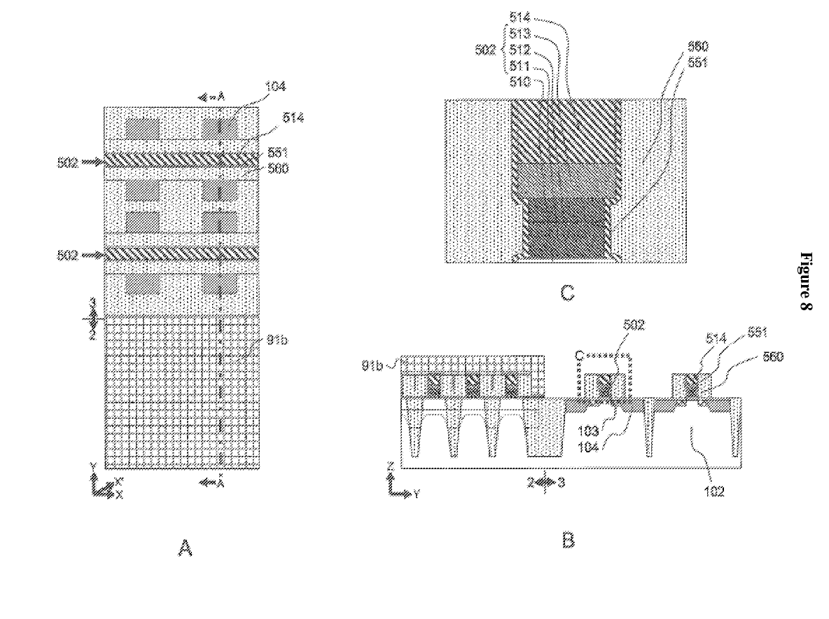

Next, as illustrated in FIG. 8, the memory cell region 2 is protected using a photoresist film 91b, and an impurity having the opposite characteristic to the peripheral circuit active regions 102 is implanted by ion implantation, in an amount greater than that in the peripheral LDD regions 103, into the peripheral circuit active regions 102, using the mask insulating film 514, the liner film 551 and the space film 560 as a mask, to form the peripheral source and drain regions 104.

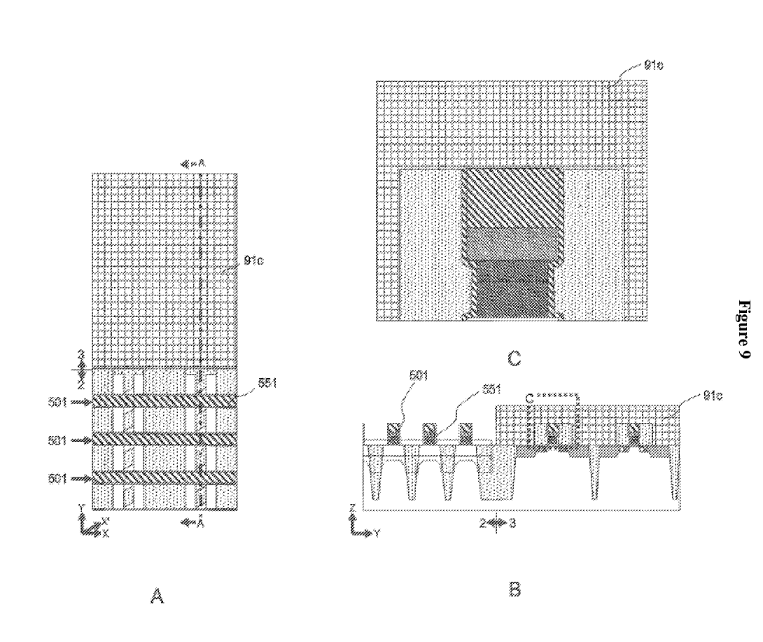

As illustrated in FIG. 9, the photoresist film 91b is then removed, after which the peripheral circuit region 3 is protected using a photoresist film 91c, and the space films 560 between the side surfaces of the bit lines 501 are removed by etch-back. It should be noted that the etch-back conditions at this time are set to conditions whereby the parts of the liner film 551 in contact with the side surfaces of the bit lines 501 remain.

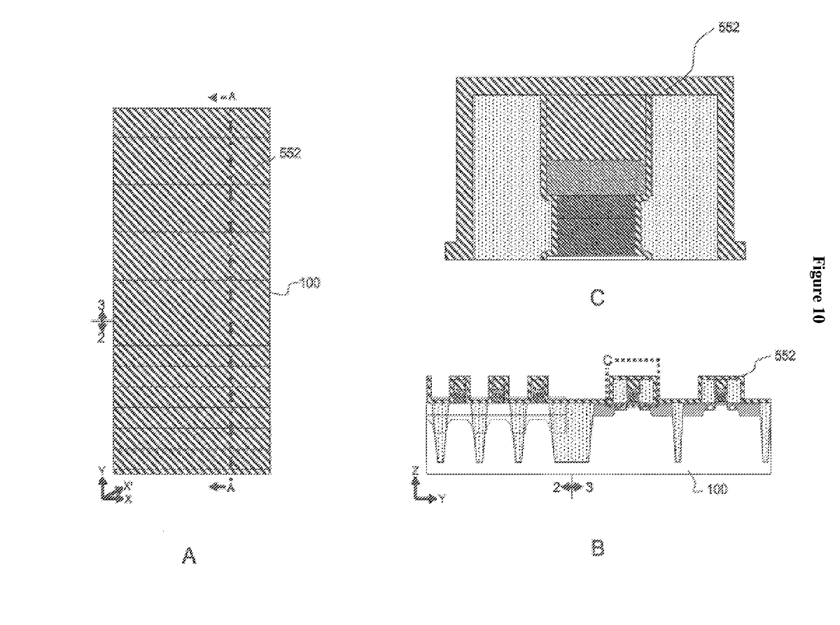

As illustrated in FIG. 10, the photoresist film 91c is then removed, after which the liner film 552, which is a silicon nitride film, is deposited by CVD over the entire surface of the semiconductor substrate 100 in the memory cell region 2 and the peripheral circuit region 3.

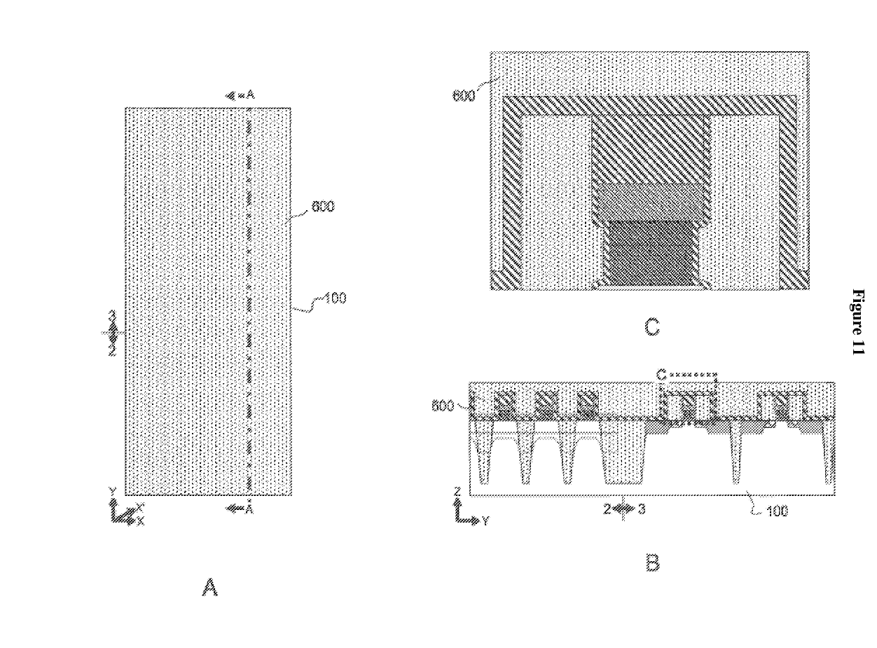

As illustrated in FIG. 11, the first interlayer insulating film 600, for example a silicon dioxide film, is then deposited by CVD or SOD application, over the entire surface of the semiconductor substrate 100 in the memory cell region 2 and the peripheral circuit region 3. At this time, if SOD application is used, the SOD is modified by heat treatment to obtain a silicon dioxide film.

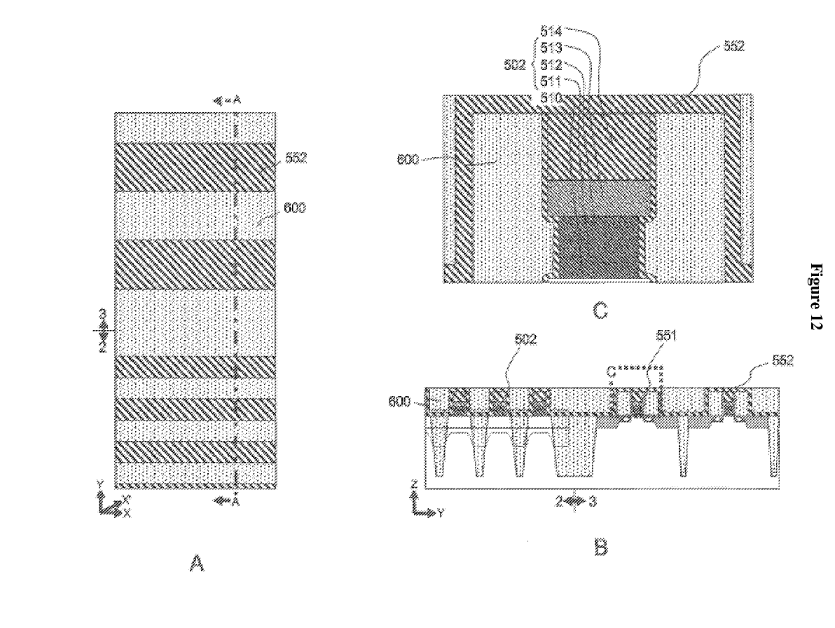

The first interlayer insulating film 600 is then polished by CMP to make it flat, as illustrated in FIG. 12. At this time, the CMP is carried out until the liner films 552 on the bit lines 501 and the gate electrodes 502 are exposed.

Next, as illustrated in FIG. 2, the liner films 552 and the first interlayer insulating film 600 are removed further, by CMP or etch-back, until the mask insulating film 514 is exposed. Known techniques are used to form the peripheral contacts 750 which penetrate through the first interlayer insulating film 600 and connect to the peripheral source and drain regions 104, and the capacitor contacts (which are not shown in the drawings) which penetrate through the first interlayer insulating film 600 and connect to the two side parts of the memory cell active regions 102. Known techniques are then used to form the peripheral wiring lines 760 connected to the peripheral contacts 750 in the peripheral circuit region 3, the stopper film 780, and the second interlayer insulating film 790. Known techniques are used to form the capacitors 800 which penetrate through the stopper film 780 and the second interlayer insulating film 790 and connect to the capacitor contacts, which are not shown in the drawings. The plate electrode 810 is then formed on the second interlayer insulating film 790 in such a way as to be connected to the upper electrodes of the capacitors 800. The third interlayer insulating film 900 is then formed in such a way as to cover the second interlayer insulating film 790, after which the wiring line contacts 910 are formed penetrating through the stopper film 780, the second interlayer insulating film 790 and the third interlayer insulating film 900, in such a way as to connect to the peripheral wiring lines 760. The wiring lines 920 are formed on the third interlayer insulating film 900 in such a way as to connect to the wiring line contacts 910, after which the protective insulating film 930 is formed in such a way as to cover the third interlayer insulating film 900. This completes the semiconductor device 1 in this mode of embodiment.

It should be noted that in the first to third modes of embodiment described hereinabove, there is no particular restriction to the material used for the metal film 513 which forms the upper gate electrodes, provided that it functions as a gate electrode. At least one film selected from a group comprising a titanium silicide film, a tungsten silicide film, a titanium nitride film, and a tungsten film can be used, for example, as the metal film 513. Further, there is no particular restriction to the high dielectric-constant insulating material contained in the gate insulating film 510, provided that it has a higher dielectric constant than that of silicon dioxide, but at least one insulating material selected from a group comprising HfSiON, ZrO₂, Ta₂O₅, Nb₂O₅, ScO₃, Y₂O₃, La₂O₃, CeO₃, Pr₂O₃, Nd₂O₃, Sm₂O₃, Eu₂O₃, Gd₂O₃, Tb₂O₃, Dy₂O₃, HO₂O₃, Er₂O₃, Tm₂O₃, Yb₂O₃, and Lu₂O₃ can, for example be used.

### EXPLANATION OF THE REFERENCE NUMBERS

1. DRAM semiconductor device
2. Memory cell region
3. Peripheral circuit region
11. Step
91a, 91b, 91c. Photoresist film
100. Semiconductor substrate
101. Memory cell active region
102. Peripheral circuit active region
103. Peripheral LDD (lightly doped drain) region
104. Peripheral source and drain region
200. Element isolation region
300. Embedded word line
501. Bit line
502. Gate electrode
505. Bit line plug
510. Gate insulating film
511. Polysilicon film
512. Polysilicon film
513. Metal film
514. Mask insulating film
550. Liner layer
551. Liner film
551′. Liner film
552. Liner film
560. Space film
600. First interlayer insulating film
610. Bit contact interlayer film
620. Opening
750. Peripheral contact
760. Peripheral wiring line
780. Stopper film
790. Second interlayer insulating film
800. Capacitor
810. Plate electrode
900. Third interlayer insulating film
910. Wiring line contact
920. Wiring line
930. Protective insulating film
D1. Oxide

1. A semiconductor device provided with a field-effect transistor comprising:
a gate insulating film which contains a high dielectric-constant insulating material, is provided with an upper surface, a bottom surface and two mutually-opposing side surfaces, is in contact at the bottom surface with a substrate, and has a first width defined by the spacing between the two side surfaces;
a lower gate electrode which opposes the substrate with the interposition of a portion of the gate insulating film, and which has a second width which is less than the first width in a direction parallel to the first width;
an upper gate electrode which covers the lower gate electrode, is provided with an upper portion, a lower portion and two mutually-opposing side portions, and has a third width in a direction parallel to the first width; and
a first spacer layer which covers the side portions of the upper gate electrode, a portion of the lower portion of the upper gate electrode, a portion of the lower gate electrode, a portion of the upper surface of the gate insulating film that is not in contact with the lower gate electrode, and the side surfaces of the gate insulating film.

2. The semiconductor device as claimed in claim 1, wherein the third width is the same as the first width, or is greater than the first width.

3. The semiconductor device as claimed in claim 1, wherein the thickness of the first spacer layer covering the upper surface and the side surfaces of the gate insulating film is greater than the thickness of the gate insulating film.

4. The semiconductor device as claimed in claim 1, additionally provided on the upper gate electrode with a mask insulating film which is in contact with the upper portion and has a third width.

5. The semiconductor device as claimed in claim 1, provided with first impurity-diffused layers formed along the first spacer layer, in the substrate on both sides of the gate insulating film, as seen in a plan view.

6. The semiconductor device as claimed in claim 5, comprising:
a second spacer layer which covers the side surfaces of the first spacer layer, and which covers the first impurity-diffused layers in the vicinity of the first spacer layer; and
second impurity-diffused layers formed along the second spacer layer, in the substrate on both sides of the gate insulating film, as seen in a plan view.

7. The semiconductor device as claimed in claim 1, comprising:
a cell transistor having a pair of impurity-diffused layers;
a capacitor connected to one of the impurity-diffused layers of the cell transistor; and
a bit line connected to the other impurity-diffused layer of the cell transistor.

8. The semiconductor device as claimed in claim 1, wherein the lower gate electrode is provided with a polysilicon film.

9. The semiconductor device as claimed in claim 1, wherein the upper gate electrode is provided with a metal film.

10. The semiconductor device as claimed in claim 9, wherein the metal film comprises at least one film selected from a group comprising a titanium silicide film, a tungsten silicide film, a titanium nitride film, and a tungsten film.

11. A method of manufacturing a semiconductor device, comprising:
forming on a substrate a gate insulating film containing a high dielectric-constant insulating material;
forming a lower gate electrode on the gate insulating film;
forming an upper gate electrode on the lower gate electrode;
patterning the upper gate electrode and the lower gate electrode;
side-etching the lower gate electrode to reduce a second width defined by the spacing between two mutually-opposing side surfaces of the lower gate electrode;
selectively removing the gate insulating film in such a way that a first width of the gate insulating film in a direction parallel to the second width is greater than the second width; and
forming a first spacer layer in such a way that it covers a side portion and a lower portion of the upper gate electrode, a side surface of the lower gate electrode, and an exposed part of the upper surface and the side surface of the gate insulating film.
